(19) United States
(12) Patent Application Publication
(10) Pub. No.: US 2006/0238984 A1
(43) Pub. Date: Oct. 26, 2006

(54) Thermal dissipation device with thermal compound recesses

(76) Inventors: Christian L. Belady, McKinney, TX (US); Eric C. Peterson, McKinney, TX (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/110,404

(22) Filed: Apr. 20, 2005

(51) Int. Cl. H05K 7/20

(52) U.S. Cl. 361/704

(57) ABSTRACT

Embodiments include apparatus, methods, and systems providing a thermal dissipation device with thermal compound recesses. In one embodiment, the thermal dissipation device includes a body with plural recesses formed in a planar surface of the body. The recesses are adapted to receive a thermal compound that conducts heat from an electronic heat generating component to the thermal dissipation device.

### BACKGROUND

Heat dissipation is an important criterion in many electronic devices and systems. Circuit boards may include a plurality of heat-generating devices that must be cooled in order to operate within a specified operating temperature. If these heat-generating devices are not sufficiently cooled, then the devices can exhibit a decrease in performance or even permanently fail.

In various electronic devices, heatsinks transfer heat away from the heat-generating device to enable the device to operate at cooler temperatures. In some instances, the heatsink is placed directly on the heat-generating device so heat transfers from the heat-generating device directly to the heatsink. Heat, however, may not efficiently transfer from the heat-generating device to the heatsink. Pockets of air can exist between the heat-generating device and the heatsink and thus reduce heat transfer. Further, the two components can have different coefficients of thermal expansion and thus impede heat transfer.

Thermal greases are placed between the heat-generating device and heatsink to improve thermal conductivity between these devices. Thermal greases, however, do not evenly distribute across the boundary or interface between the heat-generating device and the heatsink. Further, it is difficult to apply an exact amount of grease at the interface. If too little grease exists at this interface, then proper wetting of the surfaces does not occur and thermal performance is compromised. If too much grease exists at this interface, then thermal performance is also compromised due to increased conductive thickness through the grease. Further yet, excess grease can flow or seep from the joint and contaminate surrounding circuitry.

### BRIEF DESCRIPTION OF THE DRAWINGS

FIG. 1 is a perspective view of an exemplary thermal dissipation device in accordance with the present invention.

FIG. 2 is a side view of the thermal dissipation device of FIG. 1 in accordance with the present invention.

FIG. 3 is a side view of exemplary thermal dissipation devices mounted to heat generating components on a printed circuit board in accordance with the present invention.

FIG. 4 is an enlarged partial cross-sectional view of a portion of the exemplary thermal dissipation device of FIG. 3 (shown as a dashed circle) in accordance with the present invention.

FIG. 5 is a flow diagram of an exemplary method in accordance with the present invention.

FIG. 6 is a perspective view of another exemplary thermal dissipation device in accordance with the present invention.

FIG. 7 is a perspective view of another exemplary thermal dissipation device in accordance with the present invention.

### DETAILED DESCRIPTION

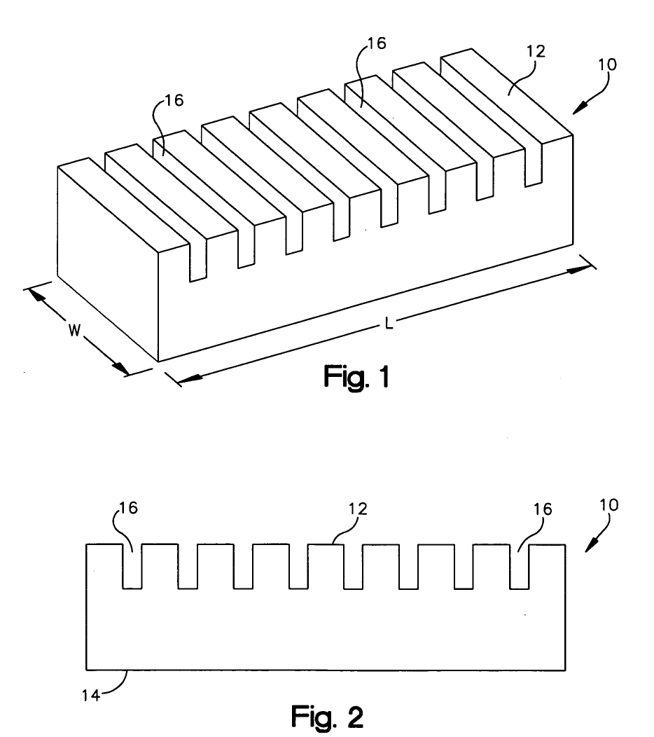

FIGS. 1 and 2 illustrate a thermal dissipation device 10 having a body with a first surface 12 and second surface 14 oppositely disposed from the first surface. One or more of the surfaces (such as first surface 12) have a plurality of recesses 16.

The recesses 16 can have a variety of configurations and still be within embodiments in accordance with the present invention. By way of example, the recesses include, but are not limited to, indentations, grooves, channels, pits, conduits, depressions, etc. The recesses are intentionally formed into the outer surface of the thermal dissipation device to receive a thermal compound. Further, the recesses have various shapes including, but are not limited to, rectangular, square, round, elliptical, angular, bent, circular, and other geometrical shapes. Further yet, the recesses can be formed with various techniques, such as machining etching, using molds, etc.

In one exemplary embodiment, the recesses 16 are elongated parallel depressions extending along all or substantially all of a length or width of one or more surfaces. In FIGS. 1 and 2, for example, the recesses 16 are formed as rectangular grooves that are uniformly distributed on the planar outer surface 12. The recesses extend across an entire length “L” and width “W” of the thermal dissipation device 10. In some embodiments, the recesses are randomly disposed on the surface; and in other embodiments (such as FIGS. 1 and 2), the recesses are non-randomly disposed on the surface.

As used herein, a “thermal dissipation device” is a device or a component designed to reduce the temperature of a heat generating device or component. The thermal dissipation devices include, but are not limited to, heat spreaders, cold plates or thermal-stiffener plates, refrigeration (evaporative cooling) plates, heat pipes, mechanical gap fillers (including plural pins, rods, etc.), thermal pads, or other devices adapted to dissipate heat. Further, thermal dissipation devices include heatsinks. A heatsink is a device or component designed to reduce the temperature of a heat-generating device. A heatsink, for example, can dissipate heat in a direct or indirect heat exchange with electronic components, the heat being dissipated into surrounding air or surrounding environment. Numerous types of heatsinks can be utilized with embodiments in accordance with the present invention. For example, embodiments can include heatsinks without a fan (passive heatsinks) or heatsinks with a fan (active heatsink). Other examples of heatsinks include extruded heatsinks, folded fin heatsinks, cold-forged heatsinks, bonded/fabricated heatsinks, and skived fin heatsinks. Further, thermal dissipation devices, including heatsinks, can utilize various liquids and/or phase change material. Further yet, thermal dissipation devices can utilize a variety of configurations to dissipate heat, such as slots, holes, fins, rods, pins, etc. Thus, thermal dissipation devices include passive heatsinks (example, heatsinks attached to a component), active heatsinks (example, fans mounted directly to the heatsink), semi-active heatsinks (example, ducted air from a fan), liquid cooled cold plates (example, dedicated cooling separate from air flow), and phase changes systems (example, heat pipes).

As used herein, a “heat generating device” or “heat generating component” includes any electronic component or device that generates heat during operation. For example, heat generating devices include, but are not limited to, resistors, capacitors, diodes, memories, electronic power circuits, integrated circuits (ICs) or chips, digital memory chips, application specific integrated circuits (ASICs), processors (such as a central processing unit (CPU) or digital signal processor (DSP)), discrete electronic devices (such as field effect transistors (FETs)), other types of transistors, or devices that require heat to be thermally dissipated from the device for the device to operate properly or within a specified temperature range.

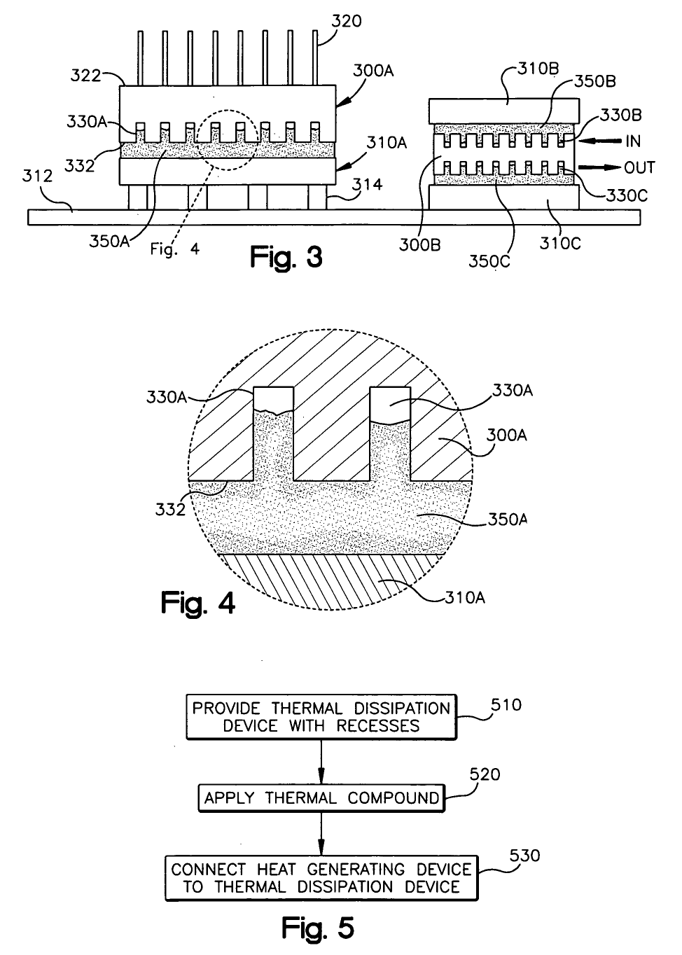

Thermal dissipation devices in accordance with embodiments of the present invention are utilized in a variety of embodiments. By way of example, FIGS. 3 and 4 illustrate a first thermal dissipation device 300A being used to dissipate heat from a first heat generating component 310A. The heat generating component 310A is mounted to a printed circuit board (PCB) 312 via pins 314 or other connectors. The thermal dissipation device 300A is placed on a top surface of the heat generating component 310A. Plural fins 320 extend upwardly from one surface 322 of the thermal dissipation device 300A. The fins are adapted to thermally dissipate or transfer heat away from the thermal dissipation device 300A and into a surrounding environment. Plural recesses 330A are disposed along a second surface 332 of the thermal dissipation device 300A. A thermal compound 350A is disposed between the thermal dissipation device 300A and the heat generating component 310A.

FIG. 3 also illustrates a second thermal dissipation device 300B being used to dissipate heat from two vertically stacked heat generating components 310B and 310C. The heat generating components 310B, 310C are mounted and electrically connected to the PCB 312. The thermal dissipation device 300B is placed between the two heat generating components. In this regard, the thermal dissipation device 300B includes two separate surface with recesses: a first surface with recesses 330B and a second surface (opposite the first surface) with recesses 330C. Plural recesses 330B are disposed along the first surface, and plural recesses 330C are disposed along the second surface. A first thermal compound 350B is disposed between the thermal dissipation device 330B and the heat generating component 310B. A second thermal compound 350C is disposed between the thermal dissipation device 330B and the heat generating component 310C. In some embodiments, the thermal compounds 350A-350C are the same compound; and in other embodiments, the thermal compounds are different.

Embodiments in accordance with the invention are not limited to any number or type of thermal dissipation devices. For example, looking to FIG. 3, the “In” and “Out” arrows signify liquid-in and liquid-out, respectively, and can be utilized with one or more thermal dissipation devices. As such, the thermal dissipation devices can be coupled to a pump and/or a heat exchanger (such as a remote heat exchanger) to circulate a cooling liquid through the thermal dissipation device to cool the thermal dissipation device 330B and/or heat generating components 310B, 310C.

Thermal compounds include, but are not limited to, thermal greases, thixotropic thermal compounds, phase change materials, thermal adhesives (such as epoxy or acrylic), thermal tapes, thermal interface pads, gap fillers, or any compound or material (electrically conductive or non-electrically conductive) that improves or maintains thermal conductivity between two surfaces or objects. In some embodiments of the present invention, the thermal compound increases or improves thermal conductivity since the compound maintains a uniform thickness across the boundary or interface of the heat generating component and thermal dissipation device. When pressure or compressive forces are applied to the heat generating component and/or thermal dissipation device, excess thermal compound flows into the recesses of the thermal dissipation device. Thus, excess compound does not flow or seep out of the boundary between the two surfaces. In one exemplary embodiment, thermal conductivity is maximized or more efficient since a minimum amount of thermal compound material is evenly distributed across the boundary between the heat generating component and the thermal dissipation device. Further, thermal compounds can be used to form a thermally conductive layer on a substrate, between electronic components, or within a finished component. For example, thermally conductive greases can be used between a heat generating device and thermal dissipating device to improve heat dissipation and/or heat transfer between the devices.

Most surfaces have a degree of roughness due to microscopic hills and valleys. Thus, even when two surfaces are brought together, space (such as a layer of interstitial air) exists between the two surfaces. Since air is a poor conductor, this space is filled with the thermal compound. The thermal compound improves heat flow or heat conduction from the heat generating component to the thermal dissipation device. When the thermal dissipation device and heat generating component are pressed or positioned together, some thermal compound flows into the recesses. For example, if excess thermal compound (such as thermal grease) is applied to one of the surfaces, then this excess will flow into the recesses and not seep from the junction. As a result, a thin uniform layer of thermal compound exists at the interface between the heat generating device and the thermal dissipation device. Further, some thermal compounds (such as silicone) tend to migrate. The recesses can accept or return some thermal compound if it migrates to ensure a uniform layer between the two surfaces.

FIG. 5 is a flow diagram of an exemplary method in accordance with the present invention. According to block 510, a thermal dissipation device is provided with recesses. For example, the recesses are intentionally manufactured on one or more surfaces of the thermal dissipation device.

According to block 520, thermal compound is applied to one or more surfaces of the thermal dissipation device. In some embodiments in accordance with the invention, the thermal compound is applied to the heat generating device. In other embodiments, the thermal compound is applied to both devices.

According to block 530, the thermal dissipation device and the heat generating device (or heat generating devices) are connected or positioned together. The devices are positioned so the thermal compound is at an interface location between opposite surfaces or opposing surfaces of the devices. The thermal compound, thus, forms a thermal junction or interface between the two components.

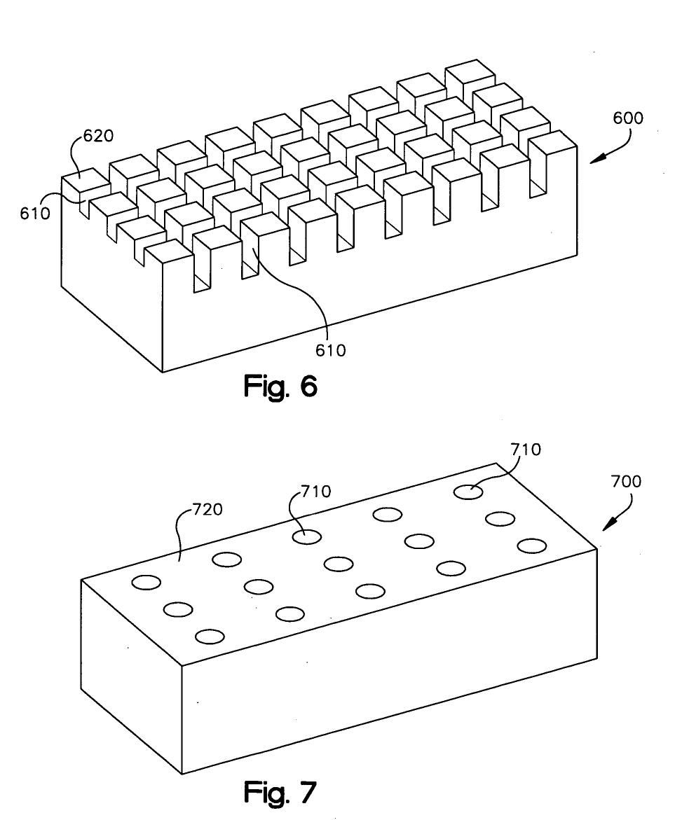

FIG. 6 is a perspective view of another exemplary thermal dissipation device 600 in accordance with the present invention. Plural recesses 610 extend along at least one surface 620 of the thermal dissipation device 600. The recesses 610 form a distinct pattern on the surface 620. In one exemplary embodiment, the pattern is a grid of rectangular channels. As used herein, a “grid” is a two or more sets of recesses that intersect each other at a fixed angle (such as a right angle).

FIG. 7 is a perspective view of another exemplary thermal dissipation device 700 in accordance with the present invention. Plural recesses 710 extend along at least one surface 720 of the thermal dissipation device 700. The recesses 710 form a distinct pattern on the surface 720. In one exemplary embodiment, the pattern is repeating series of pits or partial holes in the surface 720.

Thermal dissipation devices in accordance with the present invention can be made from a variety of materials. In some exemplary embodiments, such materials are light weight and have a high coefficient of thermal conductivity. Examples of such materials include, but are not limited to, copper, aluminum, tungsten, molybdenum, graphite, graphite-epoxy composite, or other metals, composites, and/or alloys.

One skilled in the art will appreciate that a discussion of various methods should not be construed as steps that must proceed in a particular order. Additional steps may be added, some steps removed, or the order of the steps altered or otherwise changed.

While the invention has been disclosed with respect to a limited number of embodiments, those skilled in the art will appreciate, upon reading this disclosure, numerous modifications and variations. It is intended that the appended claims cover such modifications and variations and fall within the true spirit and scope of the invention.

What is claimed is:

1) A thermal dissipation device, comprising:
a body with plural recesses formed in a planar surface of the body, the recesses adapted to receive a thermal compound that conducts heat from an electronic heat generating component to the thermal dissipation device.

2) The thermal dissipation device of claim 1, wherein the recesses are manufactured in a pattern on the planar surface.

3) The thermal dissipation device of claim 1, wherein the recesses are parallel and spaced grooves extending along substantially all of a length or width of the planar surface.

4) The thermal dissipation device of claim 1, wherein the recesses form a rectangular grid.

5) The thermal dissipation device of claim 1, wherein the recesses are evenly distributed pits formed in the planar surface.

6) The thermal dissipation device of claim 1, wherein the recesses evenly distribute the thermal compound between the planar surface and an interface with the electronic heat generating component.

7) The thermal dissipation device of claim 1, wherein the body includes a second planar surface opposite the planar surface, the second planar surface having plural recesses adapted to receive a thermal compound.

8) A thermal dissipation device, comprising:
a body with plural recesses manufactured in a surface of the body, wherein the recesses at least partially fill with a thermal compound to uniformly distribute the thermal compound between the surface and an electronic heat generating component.

9) The thermal dissipation device of claim 8, wherein the recesses have a rectangular shape.

10) The thermal dissipation device of claim 8, wherein the recesses have a circular shape.

11) The thermal dissipation device of claim 8, wherein the recesses are evenly distributed on the surface.

12) The thermal dissipation device of claim 8, wherein the recesses include parallel grooves that are evenly spaced along the surface.

13) The thermal dissipation device of claim 8, wherein the recesses fill with excess thermal compound that is applied between the surface and the heat generating component.

14) The thermal dissipation device of claim 8, wherein the recesses include two sets of grooves that intersect at right angles.

15) The thermal dissipation device of claim 8, wherein the recesses form a pattern of repeating indentations having a same geometric shape.

16) A method, comprising:
disposing a thermal compound between a surface of a thermal dissipation device and a surface of an electronic heat generating component such that at least a portion of the thermal compound flows into recesses manufactured into the surface of the thermal dissipation device.

17) The method of claim 16 further comprising forming a uniform distribution of the thermal compound between the surface of the heat generating component and the surface of the thermal dissipation device.

18) The method of claim 16 further comprising forming the recesses into a pattern on the surface of the thermal dissipation device.

19) The method of claim 16 further comprising forming the recesses into a grid of evenly spaced grooves on the surface of the thermal dissipation device.

20) The method of claim 16 further comprising filling the recesses with excess thermal compound to prevent the thermal compound from seeping from an interface formed between the surface of the thermal dissipation device and the surface of the heat generating component.
